(19) United States
(12) Patent Application Publication
(10) Pub. No.: US 2025/0098434 A1
(43) Pub. Date: Mar. 20, 2025

(54) DISPLAY PANEL AND DISPLAY APPARATUS

(71) Applicant: HKC CORPORATION LIMITED, SHENZHEN (CN)

(72) Inventors: Qin LIANG, SHENZHEN (CN); Yangling TANG, SHENZHEN (CN); Zhisheng XIE, SHENZHEN (CN); Xiufeng ZHOU, SHENZHEN (CL); Junfeng XIE, SHENZHEN (CN)

(73) Assignee: HKC CORPORATION LIMITED, SHENZHEN (CN)

(21) Appl. No.: 18/827,676

(22) Filed: Sep. 7, 2024

(30) Foreign Application Priority Data
Sep. 20, 2023 (CN) 202311230052.3

(51) Int. Cl. H10K 59/122; H10K 59/35; H10K 59/80

(52) U.S. Cl. CPC H10K 59/122; H10K 59/35; H10K 59/80515; H10K 59/80521

(57) ABSTRACT

A display panel includes: a pixel definition layer; a conductive enclosure structure, disposed on the pixel definition layer, and configured to protrude from the portion of the pixel definition layer and forming a pixel accommodation region; a plurality of sub-pixels, disposed in the pixel accommodation region along a long-edge direction of the conductive enclosure structure. The conductive enclosure structure encloses and accommodates the plurality of sub-pixels. Each of the plurality of sub-pixels includes: an anode, disposed within the pixel accommodation region; an organic light-emitting layer, arranged on the anode; a cathode, vaporized onto a surface of the organic light-emitting layer. The cathode is configured to contact with a long edge of the conductive enclosure structure, and the cathodes of the plurality of sub-pixels within the conductive enclosure structure are conductive to each other through the long edge. A moving direction of a vaporization source intersects with the long-edge direction.

### CROSS REFERENCE TO RELATED APPLICATIONS

The present disclosure claims priority to Chinese Patent Application No. 202311230052.3, filed Sep. 20, 2023, the contents of which are herein incorporated by reference in its entirety.

### TECHNICAL FIELD

The present disclosure relates to a field of display technologies, and more particular to a display panel and a display apparatus.

### BACKGROUND

Nowadays, OLED (organic light emitting diode) display screens are usually produced by an evaporation process. However, in a practical evaporation process, conductive structures within a display panel for signal transmission functions are rather complex, thereby further reducing an aperture ratio of the display panel.

### SUMMARY OF THE DISCLOSURE

A display panel and a display apparatus are provided according to embodiments of the present disclosure.

According to a first aspect of the present disclosure, a display panel is provided. The display panel includes: a driving substrate; a pixel definition layer, disposed on an upper surface of the driving substrate; a conductive enclosure structure, disposed on a surface of a portion of the pixel definition layer, and configured to protrude from the portion of the pixel definition layer and forming a pixel accommodation region; a plurality of sub-pixels, disposed in the pixel accommodation region along a long-edge direction of the conductive enclosure structure. The conductive enclosure structure is configured to enclose and accommodate the plurality of sub-pixels. Each of the plurality of sub-pixels includes: an anode, disposed on a surface of driving substrate and within the pixel accommodation region; an organic light-emitting layer, arranged on the anode; a cathode, vaporized onto a surface of the organic light-emitting layer by a vaporization source. The cathode is disposed in contact with a long edge of the conductive enclosure structure, and the cathodes of the plurality of sub-pixels within the conductive enclosure structure are conductive to each other through the long edge of the conductive enclosure structure. During a vaporization process of the cathode, a moving direction of the vaporization source intersects with the long-edge direction of the conductive enclosure structure.

In some embodiments, the conductive enclosure structure is a ring-shaped structure and surrounds the pixel accommodation region. A plurality of the conductive enclosure structures are disposed side by side along a short-edge direction of the conductive enclosure structure. Two adjacent conductive enclosure structures share a same long edge of the conductive enclosure structure. A short-edge direction of the conductive enclosure structure is parallel to the moving direction of the vaporization source.

In some embodiments, the display panel includes a plurality of sub-pixel groups of different colors. Each sub-pixel group includes a plurality of sub-pixels of a same color. A single sub-pixel group is disposed within a single corresponding pixel accommodation region. A plurality of sub-pixel groups of different colors are alternately disposed in sequence along the short-edge direction of the conductive enclosure structure.

In some embodiments, in the sub-pixel group within each conductive enclosure structure, a sub-pixel disposed at an end adjacent to a short edge of the conductive enclosure structure is referred to as an end sub-pixel, and a remaining sub-pixel in the sub-pixel group other than the end sub-pixel is referred to as a mediate sub-pixel. An end of the organic light-emitting layer of the end sub-pixel extends to contact the short edge of the conductive enclosure structure, another end of the organic light-emitting layer of the end sub-pixel is connected to the organic light-emitting layer of an adjacent mediate sub-pixel, and covers the pixel definition layer between the end sub-pixel and the adjacent mediate sub-pixel. The organic light-emitting layers of the mediate sub-pixels are interconnected with each other and cover the pixel definition layer between adjacent mediate sub-pixels.

In some embodiments, a plurality of barrier structures are further disposed within each pixel accommodation region. Each barrier structure is configured to extend along a short-edge direction of the conductive enclosure structure. The barrier structure is attached to a side surface of the pixel definition layer between the sub-pixels within a same conductive enclosure structure. The side surface is one of the two side surfaces of the pixel definition layer that is away from the driving substrate. The plurality of barrier structures and the sub-pixels within the corresponding conductive enclosure structure are alternately disposed along the long-edge direction of the conductive enclosure structure, and adjacent sub-pixels in the sub-pixel group are spaced apart from each other.

In some embodiments, the barrier structure includes at least one selected from a group consisting of an organic material, an inorganic material, and a metallic material.

In some embodiments, a cross-section of the barrier structure along a direction perpendicular to the driving substrate has at least one selected from a group consisting of a rectangular shape, a trapezoidal shape, or a conical shape.

In some embodiments, an anode connection via is further defined to penetrate one side of the driving substrate proximate to the anode. The anode connection via is misaligned with the conductive enclosure structure along a direction perpendicular to the driving substrate, and the anode connection via is at least partially overlapped with the barrier structure.

In some embodiments, the conductive enclosure structure includes a conductor and an insulator. The insulator is covered on a side of the conductor away from the driving substrate. The cathode is configured to be in conduction with the conductor.

According to a second aspect of the present disclosure, a display apparatus is further provided in embodiments of the present disclosure. The display apparatus includes a display panel. The display panel includes: a driving substrate; a pixel definition layer, disposed on an upper surface of the driving substrate; a conductive enclosure structure, disposed on a surface of a portion of the pixel definition layer, and configured to protrude from the portion of the pixel definition layer and forming a pixel accommodation region; a plurality of sub-pixels, disposed in the pixel accommodation region along a long-edge direction of the conductive enclosure structure. The conductive enclosure structure is configured to enclose and accommodate the plurality of sub-pixels. Each of the plurality of sub-pixels includes: an anode, disposed on a surface of driving substrate and within the pixel accommodation region; an organic light-emitting layer, arranged on the anode; a cathode, vaporized onto a surface of the organic light-emitting layer by a vaporization source. The cathode is disposed in contact with a long edge of the conductive enclosure structure, and the cathodes of the plurality of sub-pixels within the conductive enclosure structure are conductive to each other through the long edge of the conductive enclosure structure. During a vaporization process of the cathode, a moving direction of the vaporization source intersects with the long-edge direction of the conductive enclosure structure.

The display panel and the display apparatus are provided in embodiments of the present disclosure. The display panel may include the driving substrate, the pixel definition layer, the conductive enclosure structure, and the plurality of sub-pixels. The pixel definition layer is disposed on the upper surface of the driving substrate. The conductive enclosure structure is disposed on a surface of a portion of the pixel definition layer, and is configured to protrude from the portion of the pixel definition layer to form the pixel accommodation region. A plurality of sub-pixels are disposed in the pixel accommodation region, and are arranged along the long-edge direction of the conductive enclosure structure. The conductive enclosure structure encloses and accommodates the plurality of sub-pixels. Each sub-pixel includes the anode, the organic light-emitting layer, and the cathode. The anode is disposed on a surface of the driving substrate and within the pixel accommodation region. The organic light-emitting layer is disposed on the anode. The cathode is vaporized onto the surface of the organic light-emitting layer by the vaporization source. The cathode is disposed in contact with the long edge of the conductive enclosure structure, such that the cathodes of the plurality of sub-pixels within the conductive enclosure structure are conductive to each other through the long edge of the conductive enclosure structure. During the vaporization process of the cathode, the moving direction of the vaporization source intersects with the long-edge direction of the conductive enclosure structure. The display panel provided in the present disclosure is capable of disposing the plurality of sub-pixels within a same conductive enclosure structure. Compared to the related art which provides a single conductive enclosure structure for each sub-pixel, the technical scheme of the present disclosure may eliminate some conductive enclosure structures between the sub-pixels along the long-edge direction of the conductive enclosure structure. In this way, the conductive enclosure structure is simplified and the spacings between the plurality of sub-pixels within the conductive enclosure structure are reduced. The aperture ratio of the display panel is thereby increased, further improving the display efficiency of the display panel, and further significantly reducing a manufacturing cost of the display panel.

### BRIEF DESCRIPTION OF THE DRAWINGS

In order to more clearly illustrate technical solutions in the present disclosure, the drawings required in the description of the embodiments will be briefly introduced below. The drawings in the following description are obviously only some embodiments of the present disclosure. For those of ordinary skills in the art, other drawings could be obtained based on these drawings without creative efforts.

FIG. 1 is a schematic structural diagram of a vaporization source according to an embodiment of the related art.

FIG. 2 is a schematic structural diagram of the vaporization source of FIG. 1 and a limiting plate.

FIG. 3 is a schematic structural diagram of a display panel according to an embodiment of the related art.

FIG. 4 is a schematic sectional diagram along a direction G-G of the display panel in FIG. 3.

FIG. 5 is a schematic sectional diagram along a direction F-F of the display panel in FIG. 3.

FIG. 6 is a schematic structural diagram of a display panel according to a first embodiment of the present disclosure.

FIG. 7 is a schematic sectional diagram along a direction A-A of the display panel in FIG. 6.

FIG. 8 is a structural schematic diagram of two adjacent conductive enclosure structures in a display panel according to an embodiment of the present disclosure.

FIG. 9 is a schematic structural diagram of a display panel according to a second embodiment of the present disclosure.

FIG. 10 is a schematic sectional diagram along a direction B-B of the display panel in FIG. 9.

FIG. 11 is a schematic structural diagram of a display panel according to a specific embodiment of the present disclosure.

FIG. 12 is a schematic sectional diagram along a direction C-C of the display panel in FIG. 11.

### REFERENCE NUMBER

100, display panel; 110, conductive enclosure structure; 111, pixel accommodation region; 112, conductor; 113, insulator; 120, sub-pixel; 121, first sub-pixel; 122, second sub-pixel; 123, anode; 124, organic light-emitting layer; 125, cathode; 126, pixel definition layer; 127, sub-pixel group; 128, end sub-pixel; 129, mediate sub-pixel; 130, barrier structure; 140, driving substrate; 141, TFT device; 142, anode connection via; 210, vaporization source; 220 limiting plate.

### DETAILED DESCRIPTION

The technical scheme of embodiments of the present disclosure is described in detail below in conjunction with the accompanying drawings.

In the following description, specific details such as particular system structures, interfaces, techniques, etc. are presented for the purpose of illustration and no limitation, to facilitate a thorough understanding of the present disclosure.

Technical solutions in embodiments of the present disclosure will be described clearly and thoroughly in connection with accompanying drawing of the embodiments of the present disclosure. The described embodiments are obviously only a part of the embodiments, but not all of them. All other embodiments by a person of ordinary skills in the art based on embodiments of the present disclosure without creative efforts should all be within the protection scope of the present disclosure.

The terms ‘first’, ‘second’, and ‘third’ in this disclosure are only for the purpose of description, and cannot be construed as indicating or implying relative importance or implicitly indicating the number of technical features referred to. Therefore, the features preceded by ‘first’, ‘second’, and ‘third’ may explicitly or implicitly include at least one of the features. In the description of the present disclosure, ‘a plurality of’ means at least two, such as two, three, etc., unless otherwise specifically defined. All directional indicators (such as up, down, left, right, front, back . . . ) in embodiments of the present disclosure are only used to explain a motion state, a relative positional relationship between the components in a specific posture (as illustrated in the drawings). If the specific posture changes, then the directional indications would change accordingly. In addition, the terms ‘include’, ‘comprise’ and any variations thereof are intended to cover non-exclusive inclusion.

For example, a process, a method, a system, a product, or a device that includes a series of operations or units is not limited to the listed operations or units, but optionally includes unlisted operations or units, or optionally also includes other operations or units inherent to these processes, methods, products, or devices.

Reference to ‘embodiments’ herein means that a specific feature, structure, or characteristic described in conjunction with the embodiments may be included in at least one embodiment of the present disclosure. The appearance of this phrase in various locations in the specification does not necessarily refer to the same embodiment, nor is it an independent or alternative embodiment mutually exclusive with other embodiments. Those skilled in the art may explicitly and implicitly understand that, the embodiments described herein may be combined with other embodiments.

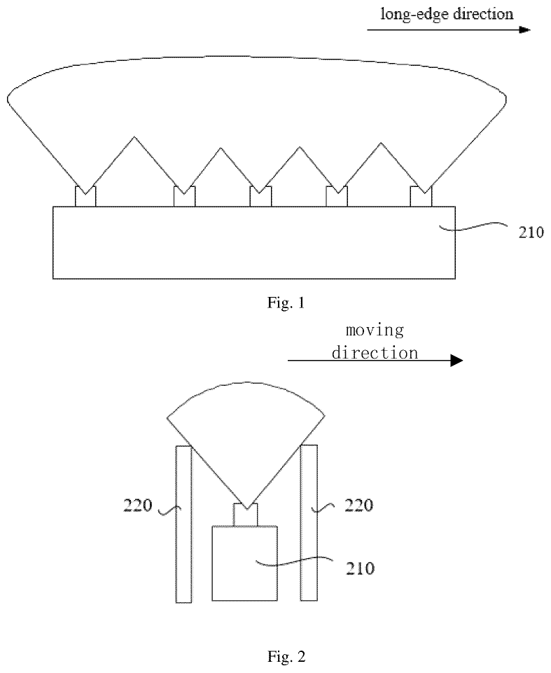

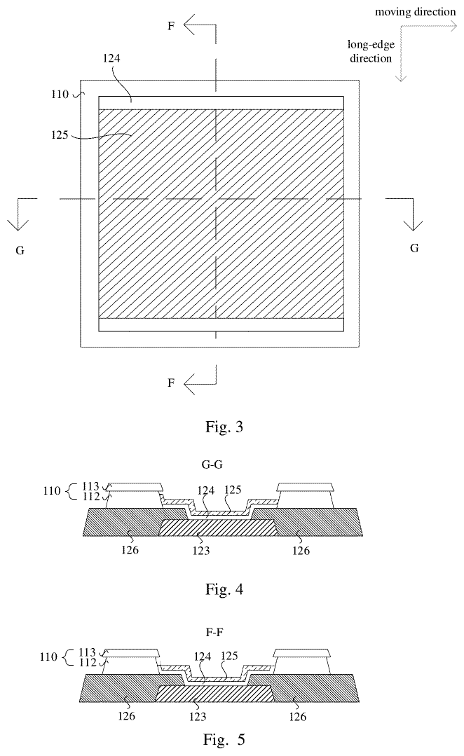

As illustrated in FIG. 1 to FIG. 5, FIG. 1 is a schematic structural diagram of a vaporization source according to an embodiment of the related art. FIG. 2 is a schematic structural diagram of the vaporization source and a limiting plate. FIG. 3 is a schematic structural diagram of a display panel according to an embodiment in the related art. FIG. 4 is a schematic sectional diagram along a direction G-G of the display panel in FIG. 3. FIG. 5 is a schematic sectional diagram along a direction F-F of the display panel in FIG. 3.

In a practical vaporization process, a vaporization source 210 may create a vaporization cloud along a long-edge direction of the vaporization source 210, a vaporization angle of vaporized material may therefore be difficult to control along the long-edge direction of the vaporization source 210. While in a moving direction of the vaporization source 210 (i.e., a scanning direction of the vaporization source 210), limiting plates 220 at both sides may be utilized to accomplish a purpose of controlling an emission angle of the vaporized material. Thus, in an existing design as illustrated in FIGS. 3-5, a conductive enclosure structure 110 may contact a cathode 125 along the moving direction of the vaporization source 210. However, a portion of the conductive enclosure structure 110 along the long-edge direction of the vaporization source 210 would not engage with the cathode 125 of a sub-pixel 120.

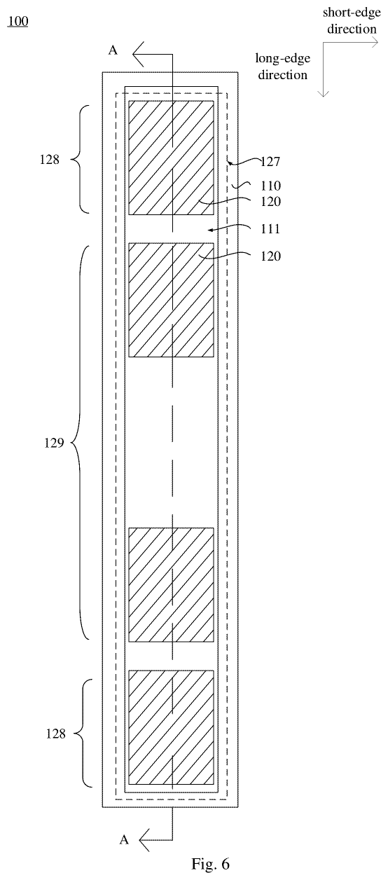

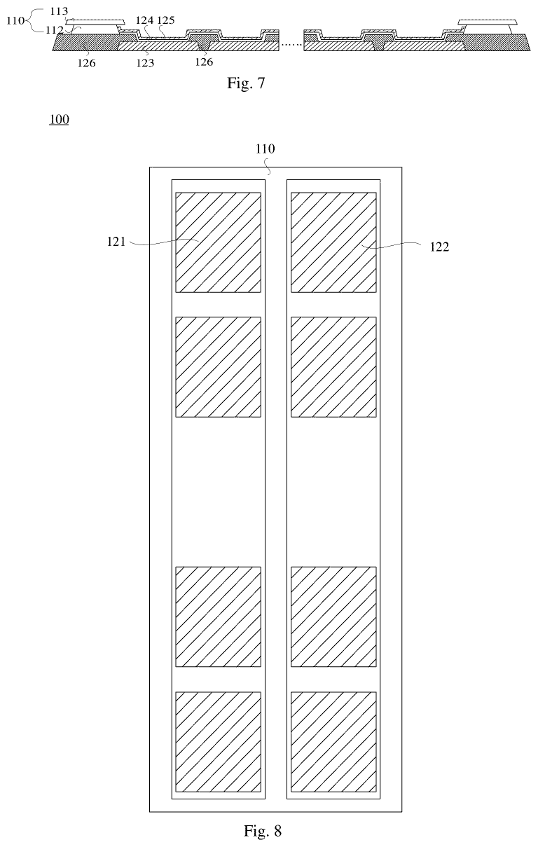

As illustrated in FIG. 6 and FIG. 7, FIG. 6 is a schematic structural diagram of a display panel according to a first embodiment of the present disclosure. FIG. 7 is a schematic sectional diagram along a direction A-A of the display panel in FIG. 5.

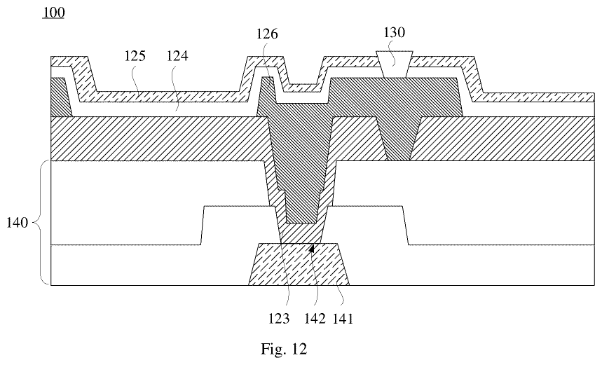

A display panel 100 is provided in the present disclosure based on the above-mentioned vaporization technology. The display panel 100 may include a driving substrate 140 (as illustrated in FIG. 12), a pixel definition layer 126, a conductive enclosure structure 110 and a plurality of sub-pixels 120. The pixel definition layer 126 is disposed on an upper surface of the driving substrate 140. The conductive enclosure structure 110 is disposed on a surface of a portion of the pixel definition layer 126, and is configured to protrude from the portion of the pixel definition layer 126 to define a pixel accommodation region 111. A plurality of sub-pixels 120 are disposed in the pixel accommodation region 111, and are arranged along the long-edge direction of the conductive enclosure structure 110. The conductive enclosure structure 110 encloses and accommodates the plurality of sub-pixels 120. Each sub-pixel 120 includes an anode 123, an organic light-emitting layer 124, and a cathode 125. The anode 123 is disposed on a surface of the driving substrate 140 and within the pixel accommodation region 111. The organic light-emitting layer 124 is disposed upon the anode 123. The cathode 125 is vaporized onto a surface of the organic light-emitting layer 124 by a vaporization source. The cathode 125 is disposed to be in contact with a long edge of the conductive enclosure structure 110, such that the cathodes 125 of the plurality of sub-pixels 120 within the conductive enclosure structure 110 are conductive to each other through the long edge of the conductive enclosure structure 110. During the vaporization process of the cathode 125, the moving direction of the vaporization source intersects with the long-edge direction of the conductive enclosure structure 110. The display panel 100 provided in the present disclosure is capable of disposing the plurality of sub-pixels 120 within a same conductive enclosure structure 110. Compared to the related art which provides a conductive enclosure structure 110 for each sub-pixel 120, the technical scheme of the present disclosure may reduce the number of conductive enclosure structures 110 between the sub-pixels 120 along the long-edge direction of the conductive enclosure structure 110. In this way, the conductive enclosure structure 110 is simplified and the spacings between the sub-pixels 120 within the conductive enclosure structure 110 are reduced. An aperture ratio of the display panel 100 is thereby increased, further improving a display efficiency of the display panel 100, and further significantly reducing a manufacturing cost of the display panel 100.

The long-edge direction of the conductive enclosure structure 110 of the present disclosure is the same as the long-edge direction of the vaporization source 210 of FIG. 1.

In the present embodiment, the plurality of sub-pixels 120 are disposed in a same conductive enclosure structure 110, thereby realizing a purpose of increasing an effective vaporization area of a pixel light-emitting region.

The driving substrate 140 is configured to drive the sub-pixels 120 to emit light. The pixel definition layer 126 is disposed between the sub-pixels 120 to separate the anodes 123 of the sub-pixels 120 from each other, thereby preventing the anodes 123 of adjacent sub-pixels 120 from conducting to each other. Mutual conduction of the anodes 123 may affect a display effect of the display panel 100.

The conductive enclosure structure 110 includes a conductor 112 and an insulator 113. The insulator 113 is covered or capped upon a side of the conductor 112 away from the driving substrate 140. The cathode 125 is configured to be in conduction with the conductor 112. Specifically, the cathode 125 of each sub-pixel 120 is configured to contact and conduct with the conductor 112 of the long edge of the conductive enclosure structure 110 in which the sub-pixel 120 is located, which in turn enables the cathodes 125 of the sub-pixels 120 within each conductive enclosure structure 110 to conduct with each other through the conductor 112 of the long edge of this each conductive enclosure structure 110.

As illustrated in FIG. 8, FIG. 8 is a structural schematic diagram of two adjacent conductive enclosure structures in a display panel according to an embodiment of the present disclosure.

The conductive enclosure structure 110 is a ring-shaped structure and is enclosed to define or surrounds the pixel accommodation region 111. As illustrated in FIG. 8. a plurality of conductive enclosure structures 110 are disposed side by side along a short-edge direction of the conductive enclosure structure 110. Two adjacent conductive enclosure structures 110 share a same long edge. The short-edge direction of the conductive enclosure structure 110 is parallel to the moving direction of the vaporization source 210.

In some embodiments, the conductive enclosure structure 110 has a rectangular cross-section in parallel with the driving substrate 140. In some other embodiments, the conductive enclosure structure 110 has a parallelogram cross-section in parallel with the driving substrate 140.

The conductive enclosure structure 110 encloses a column of sub-pixels 120. In other words, a plurality of sub-pixels 120 within the pixel accommodation region 111 are arranged in a column, and a column direction of the plurality of sub-pixels 120 is parallel to the long-edge direction of the conductive enclosure structure 110. The colors of the plurality of sub-pixels 120 enclosed in a single conductive enclosure structure 110 may be the same or different.

In some embodiments, the plurality of sub-pixels 120 enclosed in the single conductive enclosure structure 110 are all of a same color. Each conductive enclosure structure 110 is configured to enclose a same number of sub-pixels 120. In this way, when arranging the conductive enclosure structures 110, the sub-pixels 120 may be arranged in an orderly manner with the conductive enclosure structures 110, thereby simplifying a preparation process of the display panel 100.

As illustrated in FIG. 8, two adjacent conductive enclosure structures 110 share a same long edge. This ensures that, a spacing between adjacent sub-pixels 120 along the short-edge direction of the conductive enclosure structure 110 is equal, thereby facilitating a display uniformity of the display panel 100. Further, two adjacent conductive enclosure structures 110 share a same long edge, such that the conductive enclosure structures 110 may be in contact and conductive with each other. Further, the cathode 125 of each sub-pixel 120 within the conductive enclosure structure 110 is disposed to be in contact with the long edge of the conductive enclosure structure 110, such that the cathodes 125 of the sub-pixels 120 within different conductive enclosure structures 110 may also be conductive with each other. In this way, a wiring layout may be simplified and a transmission stability of signals between the cathodes 125 of the plurality of sub-pixels 120 may be guaranteed, thereby facilitating the display uniformity of the display panel 100.

In this embodiment, to demonstrate an arrangement in which adjacent conductive enclosure structures 110 sharing a same long edge, only two conductive enclosure structures 110 are illustrated. Of the two adjacent conductive enclosure structures 110, each of the sub-pixels 120 enclosed by one conductive enclosure structure 110 is referred to as a first sub-pixel 121, and each of the sub-pixels 120 enclosed by another conductive enclosure structure 110 is referred to as a second sub-pixel 122. The first sub-pixel 121 has a different color from the second sub-pixel 122. The display panel 100 of the present disclosure may include more conductive enclosure structures 110, and more sub-pixels 120 of different colors.

If a plurality of conductive enclosure structures 110 are arranged along the column direction of the sub-pixels 120, then two adjacent conductive enclosure structures 110 along the column direction of the sub-pixels 120 may share a same short edge, so as to avoid a situation in which the spacing between adjacent sub-pixels 120 along the long-edge direction of the conductive enclosure structures 110 is too great. A too great spacing may affect the display uniformity of the display panel 100.

The display panel 100 includes a plurality of sub-pixel groups 127 of different colors. Each sub-pixel group 127 includes a plurality of sub-pixels 120 of the same color. A single sub-pixel group 127 is disposed within a single corresponding pixel accommodation region 111. A plurality of sub-pixel groups 127 of different colors are alternately disposed in sequence along the short-edge direction of the conductive enclosure structure 110.

In other words, one sub-pixel group 127 is enclosed and accommodated within one conductive enclosure structure 110. The plurality of sub-pixels 120 of the same color in the sub-pixel group 127 are arranged along the long-edge direction of the conductive enclosure structure 110. The sub-pixels 120 from two adjacent sub-pixel groups 127 are of different colors. The plurality of sub-pixels 120 are arranged in an array. Sub-pixels 120 of different colors are alternately disposed in sequence along the short-edge direction of the conductive enclosure structure 110. Sub-pixels 120 of different colors are repeatedly arranged along the long-edge direction of the conductive enclosure structure 110.

As is further illustrated in FIG. 6, among the sub-pixel group 127 within each conductive enclosure structure 110, the sub-pixels 120 disposed at the ends adjacent to the short edges of the conductive enclosure structure 110 are referred to as the end sub-pixels 128, and the remaining sub-pixels 120 of the sub-pixel group 127 other than the end sub-pixels 128 are referred to as the mediate sub-pixels 129. One end of the organic light-emitting layer 124 of the end sub-pixel 128 extends to contact a corresponding short edge of the conductive enclosure structure 110. The other end of the organic light-emitting layer 124 of the end sub-pixel 128 is connected to the organic light-emitting layer 124 of an adjacent mediate sub-pixel 129, and covers the pixel definition layer 126 between the end sub-pixel 128 and the adjacent mediate sub-pixel 129. The organic light-emitting layers 124 of the mediate sub-pixels 129 are interconnected with each other and cover the corresponding pixel definition layer 126 between adjacent mediate sub-pixels 129.

In other words, the sub-pixel group 127 within each conductive enclosure structure 110 includes two end sub-pixels 128 and at least one mediate sub-pixel 129. In each sub-pixel group 127, only the end sub-pixels 128 are configured to contact with the corresponding short edges of the conductive enclosure structure 110 in which they are located, and each mediate sub-pixel 129 is configured to contact the long edge of the conductive enclosure structure 110 in which it is located. Within the pixel accommodation region 111 enclosed by each conductive enclosure structure 110, the cathode 125 of the end sub-pixel 128 and the cathode 125 of the mediate sub-pixel 129, as well as the cathodes 125 of different mediate sub-pixel 129 are interconnected together. The interconnected cathodes 125 cover the pixel definition layer 126 enclosed by this conductive enclosure structure 110. Similarly, within the pixel accommodation region 111 enclosed by each conductive enclosure structure 110, the organic light-emitting layer 124 of the end sub-pixel 128 and the organic light-emitting layer 124 of the mediate sub-pixel 129, as well as the organic light-emitting layers 124 of different mediate sub-pixel 129 are interconnected together. The interconnected organic light-emitting layers 124 cover the pixel definition layer 126 enclosed by this conductive enclosure structure 110. Compared to the related art which provides one conductive enclosure structure 110 for each sub-pixel 120, in the current structure design, a plurality of sub-pixels 120 of the same color are disposed within a conductive enclosure structure 110, and the spacing between two sub-pixels 120 of the same color within the conductive enclosure structure 110 is limited only by a pixel definition layer 126 disposed between the two sub-pixels 120. In this way, the spacing between the sub-pixels 120 may be reduced, and the aperture ratio of the display panel 100 may be increased.

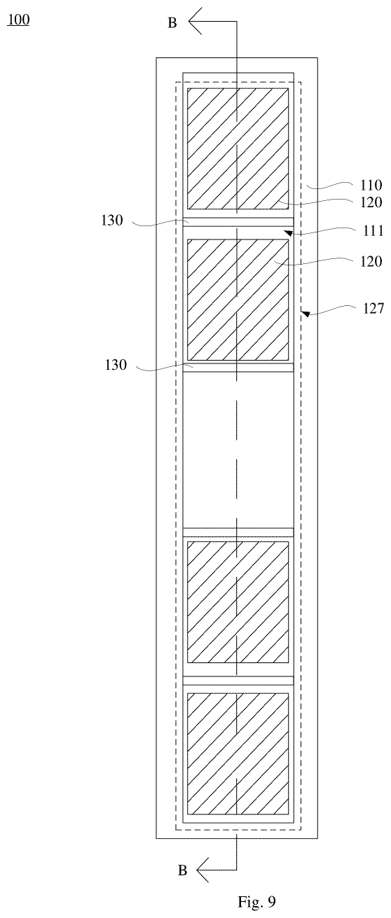

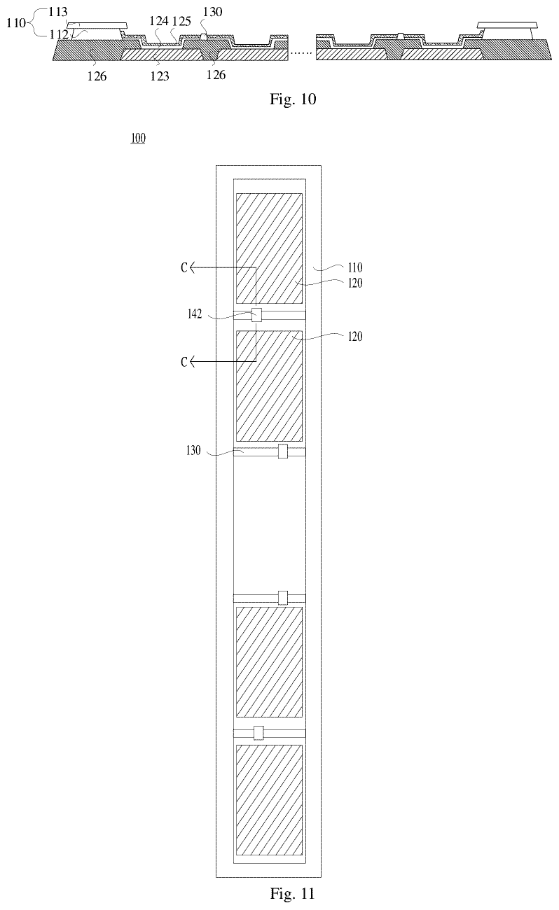

As illustrated in FIG. 9 to FIG. 12, FIG. 9 is a schematic structural diagram of a display panel according to a second embodiment of the present disclosure. FIG. 10 is a schematic sectional diagram along a direction B-B of the display panel in FIG. 9. FIG. 11 is a schematic structural diagram of a display panel according to a specific embodiment of the present disclosure. FIG. 12 is a schematic sectional diagram along a direction C-C of the display panel in FIG. 11.

The second embodiment of the display panel 100 provided in the present disclosure has a substantially similar structure with that of the first embodiment of the display panel 100 of the present application. The difference between the first embodiment and the second embodiment is that: a plurality of barrier structures 130 are further disposed within each pixel accommodation region 111. Each barrier structure 130 is configured to extend along a short-edge direction of the conductive enclosure structure 110.

In some embodiments, the plurality of barrier structures 130 are further disposed within each pixel accommodation region 111. Each barrier structure 130 is configured to extend along a direction along which a short edge of the conductive enclosure structure 110 extends. The barrier structure 130 is adhered or attached to a side surface of the pixel definition layer 126 between the sub-pixels 120 within the same conductive enclosure structure 110. The side surface is one of the two side surfaces of the pixel definition layer 126 that is away from the driving substrate 140. Further the barrier structure 130 and the sub-pixels 120 within the corresponding conductive enclosure structure 110 are alternately disposed along the long-edge direction of the conductive enclosure structure 110, such that adjacent sub-pixels 120 in the sub-pixel group 127 are spaced apart from each other.

The barrier structure 130 includes at least one selected from the group consisting of an organic material, an inorganic material, and a metallic material.

A cross-section of the barrier structure 130 along a direction perpendicular to the driving substrate 140 has at least one selected from the group consisting of a rectangular shape, a trapezoidal shape, or a conical shape. A width of the barrier structure 130 along the long-edge direction of the conductive enclosure structure 110 is less than a spacing between sub-pixels 120 within the same conductive enclosure structure 110 along the same direction. This kind of arrangement may make it easier to prepare the barrier structure 130, as well as to prevent an excessive occupation of the pixel accommodation region 111 by the barrier structure 130. The excessive occupation may affect the display effect of the display panel 100.

An anode connection via 142 is further defined to penetrate one side of the driving substrate 140 proximate to the anode 123. The anode connection via 142 is misaligned with the conductive enclosure structure 110 along a direction perpendicular to the driving substrate 140, and the anode connection via 142 is at least partially overlapped with the barrier structure 130.

The driving substrate 140 includes a TFT (Thin Film Transistor) device 141, and the anode 123 of the sub-pixel 120 is connected to the TFT device 141 through the anode connection via 142.

By defining the anode connection via 142 to overlap with the barrier structure 130 at least partially, the barrier structure 130 may be disposed above the anode connection via 142. In this way, the space between the sub-pixels 120 is not required to be occupied extra more, which facilitates the reduction of the spacing between the sub-pixels 120 and enhances the aperture ratio of the display panel 100.

The anode 124 of each sub-pixel 120 enclosed within the conductive enclosure structure 110 may be misaligned or aligned along the long-edge direction of the conductive enclosure structure 110. The specific arrangement manner may be selected based on actual needs. In some embodiments, the anode 124 of each sub-pixel 120 enclosed within the conductive enclosure structure 110 may be misaligned along the long-edge direction of the conductive enclosure structure 110.

By providing the barrier structure 130, mutual contact between the cathodes 125 of the sub-pixels 120 within the same conductive enclosure structure 110 is avoided, mutual contact between the organic light-emitting layers 124 of the sub-pixels 120 within the same conductive enclosure structure 110 is also avoided. As compared to the first embodiment of the display panel 100 of the present disclosure, pixel crosstalk between sub-pixels 120 of the same color may be prevented, thereby further optimizing the display effect of the display panel 100.

A display apparatus is further provided in some embodiments of the present disclosure. The display apparatus may include the display panel 100 recited in any of the above-mentioned embodiments. The display panel 100 of the present disclosure is an OLED (Organic Light-Emitting Diode) display panel.

In the above-mentioned embodiments, a description of each embodiment has its own focus, and a part not detailed in a certain embodiment may be referred to relevant descriptions of other embodiments.

The display panel and the display apparatus provided in the embodiments of the present disclosure are detailed above. Specific examples are applied herein to illustrate the principles and implementations of the present disclosure, and the illustrations of the above embodiments are merely for understanding the method of the present disclosure and its core ideas. Meanwhile, for those skilled in the art, variations in the specific implementations and the application scope may occur in accordance with the ideas of the present disclosure. In summary, the contents of the present specification should not be construed as a limitation to the present disclosure.

What is claimed is:

1. A display panel, comprising:
a driving substrate;
a pixel definition layer, disposed on an upper surface of the driving substrate;
a conductive enclosure structure, disposed on a surface of a portion of the pixel definition layer, and configured to protrude from the portion of the pixel definition layer and form a pixel accommodation region;
a plurality of sub-pixels, disposed in the pixel accommodation region along a long-edge direction of the conductive enclosure structure;
wherein the conductive enclosure structure is configured to enclose and accommodate the plurality of sub-pixels, each of the plurality of sub-pixels comprises:
an anode, disposed on a surface of the driving substrate and within the pixel accommodation region;
an organic light-emitting layer, arranged on the anode;
a cathode, vaporized onto a surface of the organic light-emitting layer by a vaporization source;
wherein the cathode is disposed in contact with a long edge of the conductive enclosure structure, and the cathodes of the plurality of sub-pixels within the conductive enclosure structure are conductive to each other through the long edge of the conductive enclosure structure;
wherein during a vaporization process of the cathode, a moving direction of the vaporization source intersects with the long-edge direction of the conductive enclosure structure.

2. The display panel as claimed in claim 1, wherein
the conductive enclosure structure is a ring-shaped structure and surrounds the pixel accommodation region;
a plurality of the conductive enclosure structures are disposed side by side along a short-edge direction of the conductive enclosure structure, two adjacent conductive enclosure structures share a same long edge of the conductive enclosure structure;
wherein the short-edge direction of the conductive enclosure structure is parallel to the moving direction of the vaporization source.

3. The display panel as claimed in claim 2, wherein
the display panel comprises a plurality of sub-pixel groups of different colors, each sub-pixel group comprises a plurality of sub-pixels of a same color;
a single sub-pixel group is disposed within a single corresponding pixel accommodation region, and a plurality of sub-pixel groups of different colors are alternately disposed in sequence along the short-edge direction of the conductive enclosure structure.

4. The display panel as claimed in claim 3, wherein
in the sub-pixel group within each conductive enclosure structure, a sub-pixel disposed at an end adjacent to a short edge of the conductive enclosure structure is referred to as an end sub-pixel, and a remaining sub-pixel in the sub-pixel group other than the end sub-pixel is referred to as a mediate sub-pixel;
an end of the organic light-emitting layer of the end sub-pixel extends to contact the short edge of the conductive enclosure structure, another end of the organic light-emitting layer of the end sub-pixel is connected to the organic light-emitting layer of an adjacent mediate sub-pixel, and covers the pixel definition layer between the end sub-pixel and the adjacent mediate sub-pixel;
the organic light-emitting layers of the mediate sub-pixels are interconnected with each other and cover the pixel definition layer between adjacent mediate sub-pixels.

5. The display panel as claimed in claim 4, wherein
a plurality of barrier structures are further disposed within each pixel accommodation region, each barrier structure is configured to extend along a short-edge direction of the conductive enclosure structure,
each of the plurality of barrier structures is attached to a side surface of the pixel definition layer between the sub-pixels within a same conductive enclosure structure, the side surface is one of the two side surfaces of the pixel definition layer that is away from the driving substrate,
the plurality of barrier structures and the sub-pixels within the corresponding conductive enclosure structure are alternately disposed along the long-edge direction of the conductive enclosure structure, and adjacent sub-pixels in the sub-pixel group are spaced apart from each other.

6. The display panel as claimed in claim 5, wherein
each of the plurality of barrier structure comprises at least one selected from a group consisting of an organic material, an inorganic material, and a metallic material.

7. The display panel as claimed in claim 5, wherein
a cross-section of each of the plurality of barrier structure along a direction perpendicular to the driving substrate comprises at least one selected from a group consisting of a rectangular shape, a trapezoidal shape, or a conical shape.

8. The display panel as claimed in claim 5, wherein
an anode connection via is further defined to penetrate one side of the driving substrate proximate to the anode,
wherein the anode connection via is misaligned with the conductive enclosure structure along a direction perpendicular to the driving substrate, and the anode connection via is configured to be at least partially overlapped with the barrier structure.

9. The display panel as claimed in claim 1, wherein
the conductive enclosure structure comprises a conductor and an insulator, the insulator is covered on a side of the conductor away from the driving substrate, and the cathode is configured to be in conduction with the conductor.

10. The display panel as claimed in claim 5, wherein
a width of each of the plurality of barrier structure along the long-edge direction of the conductive enclosure structure is less than a spacing between sub-pixels within a same conductive enclosure structure along the long-edge direction.

11. A display apparatus comprising a display panel, wherein
the display panel comprises:
a driving substrate;
a pixel definition layer, disposed on an upper surface of the driving substrate;
a conductive enclosure structure, disposed on a surface of a portion of the pixel definition layer, and configured to protrude from the portion of the pixel definition layer and forming a pixel accommodation region;
a plurality of sub-pixels, disposed in the pixel accommodation region along a long-edge direction of the conductive enclosure structure;
wherein the conductive enclosure structure is configured to enclose and accommodate the plurality of sub-pixels, each of the plurality of sub-pixels comprises:
an anode disposed on a surface of the driving substrate and within the pixel accommodation region;
an organic light-emitting layer, arranged on the anode;
a cathode, vaporized onto a surface of the organic light-emitting layer by a vaporization source;
the cathode is disposed in contact with a long edge of the conductive enclosure structure, and the cathodes of the plurality of sub-pixels within the conductive enclosure structure are conductive to each other through the long edge of the conductive enclosure structure;
wherein during a vaporization process of the cathode, a moving direction of the vaporization source intersects with the long-edge direction of the conductive enclosure structure.

12. The display apparatus as claimed in claim 11, wherein
the conductive enclosure structure is a ring-shaped structure and surrounds the pixel accommodation region;
a plurality of the conductive enclosure structures are disposed side by side along a short-edge direction of the conductive enclosure structure, two adjacent conductive enclosure structures share a same long edge of the conductive enclosure structure;
wherein the short-edge direction of the conductive enclosure structure is parallel to the moving direction of the vaporization source.

13. The display apparatus as claimed in claim 12, wherein
the display panel comprises a plurality of sub-pixel groups of different colors, each sub-pixel group comprises a plurality of sub-pixels of a same color;
a single sub-pixel group is disposed within a single corresponding pixel accommodation region, and a plurality of sub-pixel groups of different colors are alternately disposed in sequence along the short-edge direction of the conductive enclosure structure.

14. The display apparatus as claimed in claim 13, wherein
in the sub-pixel group within each conductive enclosure structure, a sub-pixel disposed at an end adjacent to a short edge of the conductive enclosure structure is referred to as an end sub-pixel, and a remaining sub-pixel in the sub-pixel group other than the end sub-pixel is referred to as a mediate sub-pixel;
an end of the organic light-emitting layer of the end sub-pixel extends to contact the short edge of the conductive enclosure structure, another end of the organic light-emitting layer of the end sub-pixel is connected to the organic light-emitting layer of an adjacent mediate sub-pixel, and covers the pixel definition layer between the end sub-pixel and the adjacent mediate sub-pixel;
the organic light-emitting layers of the mediate sub-pixels are interconnected with each other and cover the pixel definition layer between adjacent mediate sub-pixels.

15. The display apparatus as claimed in claim 14, wherein
a plurality of barrier structures are further disposed within each pixel accommodation region, each barrier structure is configured to extend along a short-edge direction of the conductive enclosure structure,
each of the plurality of barrier structures is attached to a side surface of the pixel definition layer between the sub-pixels within a same conductive enclosure structure, the side surface is one of the two side surfaces of the pixel definition layer that is away from the driving substrate,
the plurality of barrier structures and the sub-pixels within the corresponding conductive enclosure structure are alternately disposed along the long-edge direction of the conductive enclosure structure, and adjacent sub-pixels in the sub-pixel group are spaced apart from each other.

16. The display apparatus as claimed in claim 15, wherein
each of the plurality of barrier structure comprises at least one selected from a group consisting of an organic material, an inorganic material, and a metallic material.

17. The display apparatus as claimed in claim 15, wherein
a cross-section of each of the plurality of barrier structure along a direction perpendicular to the driving substrate comprises at least one selected from a group consisting of a rectangular shape, a trapezoidal shape, or a conical shape.

18. The display apparatus as claimed in claim 15, wherein
an anode connection via is further defined to penetrate one side of the driving substrate proximate to the anode,
wherein the anode connection via is misaligned with the conductive enclosure structure along a direction perpendicular to the driving substrate, and the anode connection via is configured to be at least partially overlapped with the barrier structure.

19. The display apparatus as claimed in claim 11, wherein
the conductive enclosure structure comprises a conductor and an insulator, the insulator is covered on a side of the conductor away from the driving substrate, and the cathode is configured to be in conduction with the conductor.

20. The display apparatus as claimed in claim 15, wherein
a width of each of the plurality of barrier structure along the long-edge direction of the conductive enclosure structure is less than a spacing between sub-pixels within a same conductive enclosure structure along the long-edge direction.
